(19) United States
(12) Patent Application Publication
(10) Pub. No.: US 2012/0250323 A1
(43) Pub. Date: Oct. 4, 2012

(54) ASSEMBLY OF LIGHT EMITTING DIODES

(76) Inventor: Pannirselvam A/L Velu, Penang (MY)

(21) Appl. No.: 13/231,615

(22) Filed: Sep. 13, 2011

(30) Foreign Application Priority Data
Mar. 30, 2011 (NZ) 592011

(51) Int. Cl. F21V 21/00; H01L 33/62

(52) U.S. Cl. 362/249.02; 438/28; 257/E33.056

(57) ABSTRACT

A light emitting diode (LED) array including an assembly of LED packages is provided. The LED packages are mounted to a face of a substructure including a circuit board and a heat transfer plate. Each LED package includes electrical connection terminals and a thermal connection pad, the electrical connection terminals are electrically connected to respective circuit conductors of the circuit board, the thermal pads are connected to the heat transfer plate by respective thermally conductive connections, and at least one of the LED packages is tilted at an angle relative to an adjacent portion of the face of the substructure.

### PRIORITY

This application claims priority under 35 U.S.C. §119(a) to an application entitled “An Assembly Of Light Emitting Diodes” filed in the New Zealand Intellectual Property Office on Mar. 30, 2011 and assigned Serial No. 592011, the contents of which are incorporated herein by reference.

### FIELD OF INVENTION

The present invention relates to light emitting diode (LED) lamps, more particularly to integrated LED lamps providing improved performance and relatively high levels of illumination suitable for replacement of conventional incandescent light bulbs and non-tubular fluorescent lamps, and most particularly to an assembly of multiple LED packages suitable for use in such a lamp.

### BACKGROUND

LED lamps are widely recognized as the next generation of lighting solutions and as a potential replacement for conventional incandescent light bulbs and fluorescent lighting systems. However, while existing LED lamps exhibit improved efficiency, producing more light per watt of input power, characteristics inherent to LEDs have prevented general acceptance of LED lamps in the general market. In particular, high LED operating temperatures and narrow LED light output beams are inherent limitations of LEDs that have restricted the general acceptance of LED lamps.

High power LEDs (for example, LEDs operating at above 0.5 watts) operate at relatively high temperatures due to limitations of current practices on the removal of the heat dissipated by the LED. These high operating temperatures increase the rate of degradation of light output over the life of LED lamps, and limit the rated life of known LED lamps.

Although available LED packages can achieve levels of light output per watt of electrical power input that rival or exceed previous standard technologies, for example, florescent lamps and particularly compact fluorescent lamps (CFLs), the higher performance of the LED packages is only achieved when excellent thermal management is practiced. In particular, sufficient heat must be dissipated to maintain the LED dies or junctions below critical temperatures. Typically, this is only achieved under laboratory conditions. The inferior thermal performance of LED packages mounted in LED lamps for commercial application results in the light output performance of these LED lamps being below that indicated by the maximum theoretical capability of the LED packages.

It is known to mount LEDs, in the form of LED dies or packages, on flame-resistant glass-reinforced epoxy laminate printed circuit board materials, commonly referred to by the NEMA (National Electrical Manufacturers' Association) classification FR-4, or polyimide-based flexible circuit materials. However, mounting of high power LEDs on these materials is preferably avoided because the relatively low thermal conductivity of these materials (for example, 0.3 W/m K for FR-4 and polyimide materials, compared with about 400 W/m K for copper), limits the maximum input power achievable without exceeding the maximum LED operating temperatures, and because the high LED operating temperatures reduce the rated operating life of the LEDs due to the increased rate of the temperature-induced degradation of light output.

In one attempt to alleviate problems caused by high operating temperatures, current high power LEDs are typically mounted on metal core printed circuit boards (MCPCBs), on ceramic based substrates, or on anodized aluminium substrates which have printed circuitry.

MCPCB's are typically made by sandwiching two metals between a thermally conductive dielectric. One of the metal layers is typically copper for good electrical connectivity and thermal conductivity, typically 400 W/m K. The other metal layer is usually of aluminium (typical thermal conductivity 250 W/m K) for acting as a heat spreader. The intermediate dielectric layer, which intervenes between the LEDs and the heat spreading aluminium layer, is of relatively low thermal conductivity, typically 1-4 W/m K. Improvements in performance of lamps using LEDs mounted on MCPCBs are limited, primarily because of the poor thermal conductivity of this intermediate dielectric material.

Various ceramic materials having superior thermal conductivities can be used as an electrical insulation material for mounting of high powered LEDs. Alumina, which has a typical thermal conductivity of 33 W/m K, is increasingly becoming the preferred material for use with high powered LEDs. Boron nitride (typical thermal conductivity 55 W/m K), aluminium nitride (typical thermal conductivity 117 W/m K), and beryllium oxide (typical thermal conductivity 251 W/m K), are also suitable, but are not economically viable due to their high cost.

LEDs typically produce light within a relatively narrow beam, which in the case of most high brightness LEDs has a beam angle of 120°. The beam angle is defined as the angle between points on opposite sides of the beam axis where the light intensity drops to 50% of the maximum intensity. The ceramic and MCPCB materials mentioned above provide a rigid planar surface on which the LEDs are mounted. LED lamps using LEDs mounted on these materials suffer from poor distribution and spread of light output due to the relatively narrow beam angle of the individual LEDs. Known LED lamps produce a limited spread of light output with ‘spotty’ effects, i.e. where unacceptable variations in output light intensity are apparent.

The Energy Star program, facilitated by the United States Department of Energy, has published minimum performance criteria for integral LED lamps intended to replace existing standard omnidirectional electric lamps. These criteria state that these LED lamps:
“shall have an even distribution of luminous intensity within the 0° to 135° zone (vertically axially symmetrical). Luminous intensity at any angle within this zone shall not differ from the mean luminous intensity for the entire 0° to 135° zone by more than 20%. At least 5% of total flux must be emitted in the 135° to 180° zone.”

The angular zones are referenced to an omnidirectional lamp positioned with its longitudinal axis aligned vertically and its connecting base uppermost.

LED lamps using limited beam angle LEDs mounted on a rigid planar substrate, such as a MCPCB or a ceramic material, require additional modification to meet the standard Energy Star requirements for even distribution and spread of light.

Several methods are currently practiced to overcome the uneven distribution and limited spread of light output from LED lamps. In one approach, secondary diverging lenses are mounted onto each individual LED package to widen the LED beam spread. In addition to extra costs for the lens and its assembly onto the LED array, the light output is diminished due to absorption within the lens and at the lens interfaces due to refractive index mismatches.

In another approach, the LED lamp includes an emissive coating that converts light output from the LEDs. In one example, the LEDs emit a blue light which is converted by a phosphor coating which emits white light. As well as providing an improvement in the colour of the light, the evenness of the light distribution and the beam spread are improved. Disadvantages are lower efficiency and the high cost of the phosphor coating.

In yet another approach to address light spread limitations, LED packages are mounted on both horizontal and vertical surfaces. Disadvantages of this approach are difficulties with high assembly costs and thermal management, particularly in high power LED lamps. This approach may be suited for lower power LEDs, where there is less heat to be managed. Furthermore, in known LED lamps, the LEDs are typically mounted on planar, i.e. flat, substrates using surface mount machines that are designed to work on flat surfaces. Mounting LEDs simultaneously on more than one plane poses a manufacturing challenge for high volume applications.

In this specification where reference has been made to patent specifications, other external documents, or other sources of information, this is generally for the purpose of providing a context for discussing the features of the invention. Unless specifically stated otherwise, reference to such external documents or such sources of information is not to be construed as an admission that such documents or such sources of information, in any jurisdiction, are prior art or form part of the common general knowledge in the art.

### SUMMARY OF INVENTION

An object of at least one embodiment of the invention is to provide an LED array comprising an assembly of LED packages, the LED packages being mounted on a face of a substructure, and at least one of the LED packages being tilted away from adjacent portions of the face of the substructure, or at least to provide the public with a useful choice.

Another object of at least one embodiment of the invention is to provide an LED array having LED packages mounted on a substantially planar substructure and oriented to emit light over a wider angle with improved evenness of dispersion than achievable with any one of the LED packages alone.

Another object of at least one embodiment of the invention is to provide a method of manufacturing an LED array comprising an assembly of LED packages, the LED packages being mounted on a face of a substructure, the method comprising tilting at least one of the LED packages away from adjacent portions of the face of the substructure.

In a first aspect the invention may be broadly said to be a light emitting diode (LED) array comprising an assembly of LED packages, wherein:
the LED packages are mounted to a face of a substructure;
the substructure comprises a circuit board and a heat transfer plate;
each LED package comprises electrical connection terminals and a thermal connection pad;
the electrical connection terminals are electrically connected to respective circuit conductors of the circuit board;
the thermal pads are connected to the heat transfer plate by respective thermally conductive connections; and
at least one of the LED packages is tilted at an angle relative to an adjacent portion of the face of the substructure.

Preferably, the electrical connections of the electrical connection terminals to the respective circuit conductors are made by soldered connections.

Preferably, the thermally conductive connections of the thermal pads to the heat transfer plate are made by soldered connections.

Preferably, the circuit board comprises a respective tab for each LED package; portions of the circuit conductors extend onto each tab; and the electrical connections of the electrical connection terminals to the respective circuit conductors are made at the portions of the circuit conductors on the respective tabs. Preferably, the circuit board comprises an electrically insulative base layer; the circuit conductors are formed on a face of the base layer; and peripheral edge portions of each tab are defined respectively by at least one perimeter slot formed through the base layer of the circuit board. Preferably, each tab comprises a hinge line provided by a respective hinge slot formed through the base layer of the circuit board. Preferably, each tab comprises an aperture formed through the base layer; and the thermally conductive connection of the thermal pad of a respective LED package to the heat transfer plate is made through the aperture.

Preferably, localised protrusions extend from a face of the heat transfer plate; and the thermally conductive connections of the thermal pads of the LED packages are made respectively to the protrusions of the heat transfer plate.

Preferably, the circuit board comprises a respective tab for each LED package; each tab comprises an aperture formed through the circuit board; localised protrusions extend from a face of the heat transfer plate; each protrusion extends at least partially through a respective one of the apertures; and the thermally conductive connections of the thermal pads of the LED packages are made respectively to the protrusions. Preferably, the circuit board other than the tabs is substantially planar. Preferably, each of the localised protrusions extends above adjacent portions of the face of the heat transfer plate by a distance that is greater than the thickness of the circuit board. Preferably, the heat transfer plate comprises a heat transfer tab for each respective LED package; the localised protrusions are located respectively on the heat transfer tabs; and peripheral edge portions of each heat transfer tab are defined respectively by at least one perimeter slot formed through the heat transfer plate. Preferably, the heat transfer plate other than the heat transfer tabs is substantially planar.

Preferably, at least one of the LED packages is tilted at an angle of at least about 15 degrees relative to the adjacent portion of the face of the substructure. Preferably, at least one of the LED packages is tilted at an angle of at least about 60 degrees relative to the adjacent portion of the face of the substructure. Preferably, at least one of the LED packages is tilted at an angle of at least about 75 degrees relative to the adjacent portion of the face of the substructure.

Preferably, at least one of the LED packages is tilted at an angle of less than about 90 degrees relative to the adjacent portion of the face of the substructure.

In a second aspect the invention may be broadly said to be a LED lamp comprising a LED array as claimed in any one of the preceding claims.

In a third aspect the invention may be broadly said to be a method of manufacturing a light emitting diode (LED) array comprising an assembly of LED packages, each LED package comprising electrical connection terminals and a thermal connection pad; the method comprising:
mounting the LED packages to a face of a substructure comprising a circuit board and a heat transfer plate;

the mounting being performed by:
connecting the electrical connection terminals of each LED package to circuit conductors of the circuit board by respective electrical connections; and
connecting the thermal pads to the heat transfer plate by respective thermally conductive connections;

and, subsequently to mounting the LED packages to the substructure;
tilting at least one of the LED packages at an angle relative to an adjacent portion of the face of the substructure.

Preferably, the electrical connections of the electrical connection terminals to the circuit conductors are made by soldered connections.

Preferably, the thermally conductive connections of the thermal pads to the heat transfer plate are made by soldered connections.

Preferably, a respective localised protrusion is formed on a face of the heat transfer plate for each LED package; and the thermally conductive connections are made by:
placing solder paste on each protrusion;
placing the LED packages on the heat transfer plate with the thermal pads aligned respectively with, and resting on, the solder paste on the protrusions; and
temporarily melting the solder paste on the protrusions to form the thermally conductive connections.

Preferably, the step of temporarily melting the solder paste on the protrusions is performed by placing the heat transfer plate on at least one heated plate, with the heat transfer plate in thermally conductive contact with the heated plate, to heat and temporarily melt the solder paste on the protrusions by conduction of heat from the heated plate.

Alternatively, the step of temporarily melting the solder paste on the protrusions is performed by placing the heat transfer plate successively on each plate of a series of heated plates, with the heat transfer plate successively in thermally conductive contact with each of the heated plates, to heat and temporarily melt the solder paste on the protrusions by conduction of heat from the heated plates. Preferably, each plate of the series of heated plates is heated to a different temperature.

Preferably, each of the localised protrusions extends above adjacent portions of the face of the heat transfer plate by a distance that is greater than the thickness of the circuit board.

Preferably, the electrical connections are made by soldered connections by:
placing solder paste on each of the circuit conductors;
placing the LED packages on the circuit board with the electrical connection terminals aligned respectively over the solder paste on the circuit conductors; and
temporarily melting the solder paste on the circuit conductors to form the electrical connections.

Preferably, the step of temporarily melting the solder paste on the circuit conductors is performed by heating the circuit board, with the LED packages placed thereon, in a convection oven.

Preferably, the soldered electrical connections are made before the thermally conductive connections are made. Preferably, the soldered electrical connections formed between the electrical connection terminals and the circuit conductors are maintained in a solid, not molten, state during the making of the thermally conductive connections. Preferably, a respective aperture is formed in the circuit board for each LED package; in the step of placing the LED packages on the circuit board, the LED packages are placed on the circuit board with the thermal pads aligned respectively over the apertures; and in the step of placing the LED packages on the heat transfer plate, the circuit board, with the LED packages attached to the circuit board by the soldered electrical connections, is placed over the heat transfer plate with the protrusions respectively extending at least partially through the apertures. Preferably, each aperture is located on a respective tab; each tab is formed by creating at least one perimeter slot through the circuit board to define peripheral edge portions of the respective tab; portions of the electrical conductors are located on each tab; and the electrical connections are made respectively to the portions of the electrical conductors located on the tabs. Preferably, each tab comprises a hinge line provided by a respective hinge slot formed through the circuit board. Preferably, the circuit board other than the tabs is substantially planar. Preferably, the placing of solder paste is performed by a screen printing, pin transfer or jet printing process. Preferably, the placing of the LED packages is performed by a machine using a surface mount technology. Preferably, the heat transfer plate is a sheet of thermally conductive material and the localised protrusions are formed by stamping the sheet of thermally conductive material. Preferably, each localised protrusion is located on a respective heat transfer tab formed in the heat transfer plate by creating perimeter slots through the heat transfer plate to define peripheral edge portions of the heat transfer tab. Preferably, the heat transfer plate other than the heat transfer tabs is substantially planar. Preferably, the tilting of the at least one LED package is performed by applying a punch against the heat transfer plate to move the at least one LED package away from the respective adjacent portion of the substructure.

In a fourth aspect the invention may be broadly said to be a method of manufacturing a LED lamp comprising light emitting diode array manufactured by the method according to the third aspect or any of its preferences or alternatives.

In a fifth aspect the invention may be broadly said to be a LED array manufactured by the method according to the third aspect or any of its preferences or alternatives.

In a sixth aspect the invention may be broadly said to be a LED lamp comprising a LED array manufactured by the method according to the third aspect or any of its preferences or alternatives.

This invention may also be said broadly to consist in the parts, elements and features referred to or indicated in the specification of the application, individually or collectively, and any or all combinations of any two or more said parts, elements or features, and where specific integers are mentioned herein which have known equivalents in the art to which this invention relates, such known equivalents are deemed to be incorporated herein as if individually set forth.

To those skilled in the art to which the invention relates, many changes in construction and widely differing embodiments and applications of the invention will suggest themselves without departing from the scope of the invention as defined in the appended claims. The disclosures and the descriptions herein are purely illustrative and are not intended to be in any sense limiting.

The term ‘comprising’ as used in this specification or in the accompanying claims means ‘consisting at least in part of’, that is to say when interpreting statements in this specification or in the accompanying claims which include that term, the features, prefaced by that term in each statement, all need to be present but other features can also be present.

As used in this specification, the term “and/or” means “and” or “or”, or both.

As used in this specification, a noun followed by “(s)” means the singular and/or plural forms of the noun.

As used in this specification, the acronym “LED” means light emitting diode, and “LEDs” means light emitting diodes.

As used in this specification, the term “LED package” means an assembly of one or more LED dies with wire bond or other type of electrical connection for connection between elements of the package, thermal and electrical interfaces for external connection to the package, and optionally a lens, diffuser, reflector, or other optical element.

As used in this specification, the term “LED array” means an assembly of LED packages on a printed circuit board or substrate, and optionally with additional optical elements and thermal, mechanical, and electrical interfaces.

As used in this specification, the term “LED lamp” means a lamp with a LED array and a base designed for mounting the lamp in an electrical socket and for connecting the lamp to an electrical supply circuit.

As used in this specification, the term “LED driver” means a power supply with integral LED control circuitry designed to meet the specific requirements of a LED array or a LED lamp.

As used in this specification, the term “integral LED lamp” means a lamp with an LED array, an integrated LED driver, and a base designed for mounting the lamp in an electrical socket and for connecting the lamp to an electrical supply circuit.

As used in this specification in respect of LED packages, the term “front side” means the side of the LED package from which light is primarily emitted, and the term “rear side” means the side of the LED package that is opposite the front side. These meanings are independent of the orientation of the LED package on a substructure or substrate, or in a LED array, or in a LED lamp. For example, when a LED package is positioned on a circuit board ready to be soldered to the circuit board, a lens on the front side of the LED package is typically facing upward and the electrical and thermal connection pads on the rear side of the LED package are typically facing downward, whereas, when the LED package is used in a LED lamp mounted in a standardised ceiling socket to project light primarily downward, the lens on the front side of the LED package will typically be facing downward and the electrical and thermal connection pads on the rear side of the LED package will typically be facing upward.

### BRIEF DESCRIPTION OF THE DRAWINGS

Preferred embodiments and methods of utilising the invention will be further described by way of example only and without intending to be limiting, with reference to the accompanying figures in which:

FIG. 1 shows a front side perspective view of a light emitting diode (LED) array according to the present invention, with LED packages facing upward;

FIG. 2 shows an exploded front side perspective view of LED packages, circuit board and heat transfer plate, prior to assembly of the LED array of FIG. 1;

FIG. 3 shows a cross-sectional view through an LED package mounted on the circuit board and heat transfer plate at an intermediate step in the manufacture of the LED array of FIG. 1, with the LED package facing upward;

FIG. 4 shows a plan view of the front side of the circuit board used in the LED array of FIG. 1;

FIG. 5 shows a plan view of the front side of a tab at the portion of the circuit board circled A in FIG. 4;

FIG. 6 shows a perspective view of the rear side of the tab portion of the circuit board shown in FIG. 5;

FIG. 7 shows a perspective view of LED packages mounted on the circuit board, at an intermediate step in the manufacture of the LED array of FIG. 1, with the LED packages facing upward;

FIG. 8 shows a perspective view of the front side of the heat transfer plate used in the LED array of FIG. 1;

FIG. 9 shows a schematic elevation of the LED array of FIG. 1, shown inverted with LED packages facing downward, illustrating punch actions directed to tilt the LED packages;

FIG. 10 shows an elevation of the LED array of FIG. 1, shown inverted with LED packages facing downward, with both the inner and outer rings of the LED packages tilted at about 15 degrees to the general planes of the circuit board and heat transfer plate;

FIG. 11 shows an elevation of an alternative LED array, shown inverted with LED packages facing downward, with the inner and outer rings of LED packages tilted respectively at about 15 degrees and about 75 degrees to the general planes of the circuit board and heat transfer plate; and

FIG. 12 shows an elevation of an LED lamp incorporating the alternative LED array shown in FIG. 11.

### DETAILED DESCRIPTION OF EMBODIMENTS OF THE INVENTION

Referring to the figures it will be appreciated that the invention may be implemented in various forms and modes. The following description of embodiments of the invention is given by way of example only.

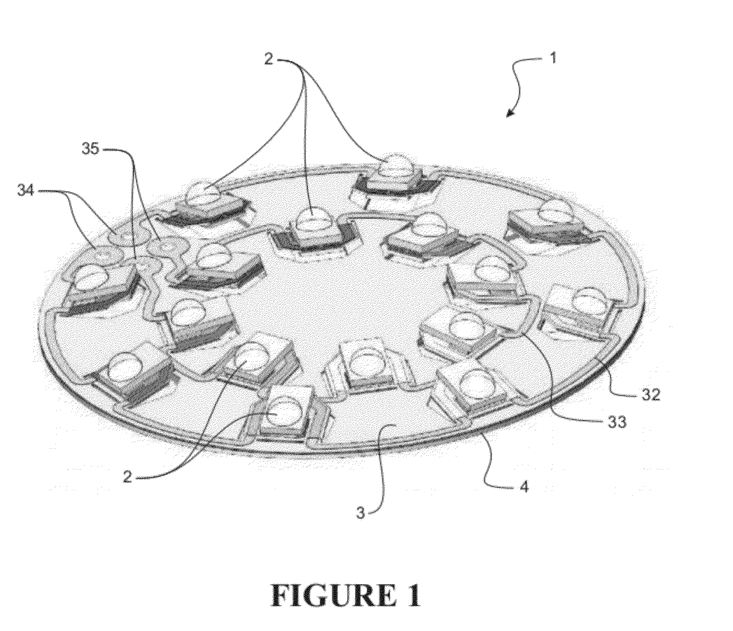

FIG. 1 shows a light emitting diode (LED) array 1. The LED array comprises an assembly of LED packages 2. The LED packages are mounted on a substructure which comprises a circuit board 3 and an underlying heat transfer plate 4.

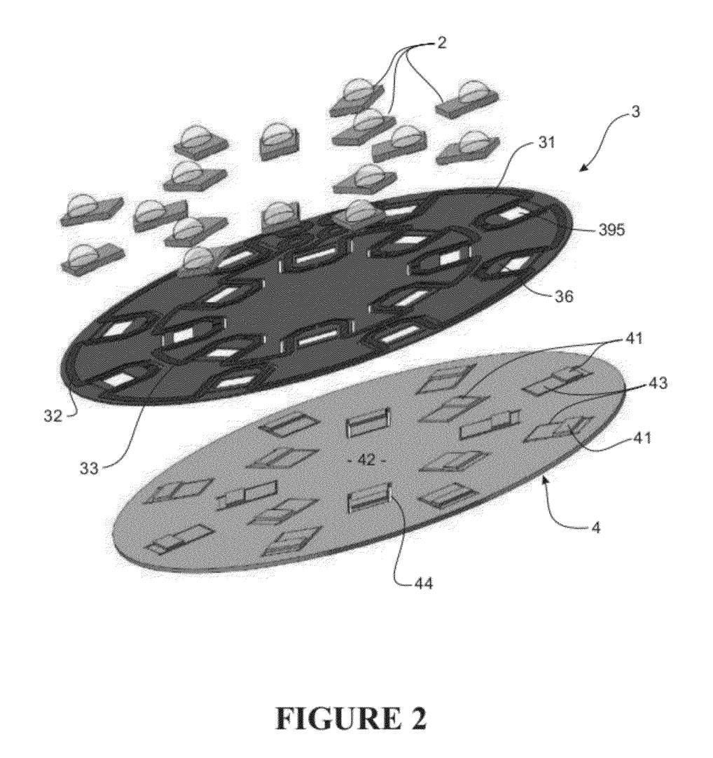

FIG. 2 shows the LED packages 2, the circuit board 3 and the heat transfer plate 4 discretely in an exploded view of the LED array.

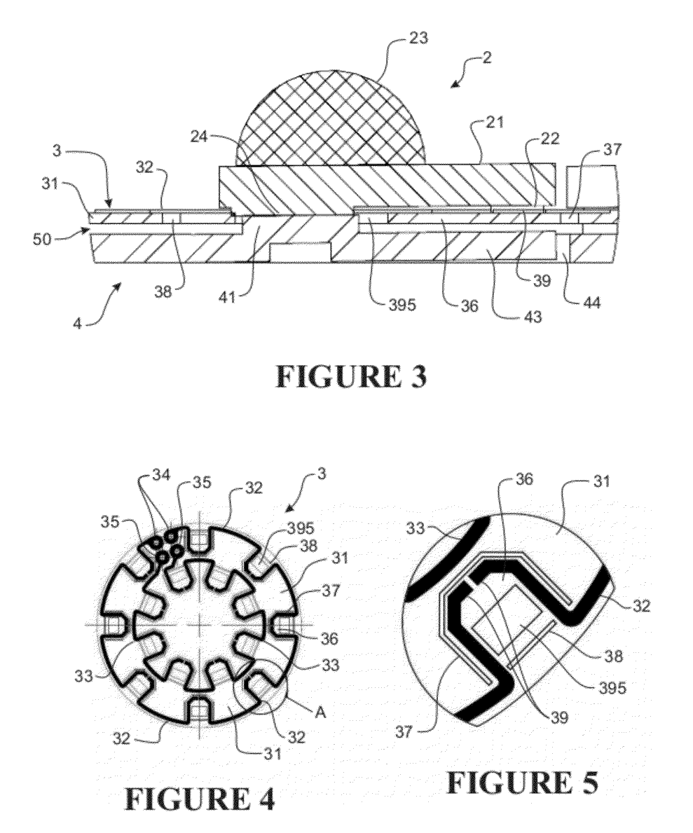

FIG. 3 shows a cross-sectional view of one of the LED packages 2 mounted on the substructure. Each LED package comprises a substrate 21 with a light emitting diode die (not shown) attached to a front side of the substrate. Wires (not shown) are bonded to the light emitting diode die to form part of electrical connections between the die and anode and cathode terminals 22 on the rear side of the substrate 21. An optical lens 23 on the front side of the substrate encapsulates the die and bonded wires. Heat generated during operation of the LED package is dissipated through a thermal pad 24 provided on the rear side of the substrate. The exterior surface of the thermal pad 24 is preferably substantially co-planar with the exterior surface of each of the anode and cathode terminals 22.

FIGS. 4 and 5 show front plan views of the circuit board 3 which comprises an electrically insulative substantially planar base layer 31 with electrically conductive circuits 32, 33 formed on a front side face (the upper face as seen in FIGS. 1, 2, 4, 5 and 7) of the base layer.

The base layer 31 is made of material having a relatively low thermal conductivity. A preferred material is a polyimide. The thermal conductivity of a preferred polyimide is about 0.3 W/m-K. The thickness of the polyimide base layer is preferably in the range 0.025 mm to 0.150 mm. An alternative preferred base layer material is polyester.

The electrically conductive circuit layer is adhered to the base layer by an adhesive. The adhesive is preferably an acrylic, epoxy, or phenolic butyral, or a pressure sensitive adhesive (PSA), or a pre-impregnated FR-4/polyimide. The conductive circuit material is preferably copper, or beryllium copper, cupro-nickel, nickel, silver, or silver epoxy. The conductive layer is formed into circuit tracks 32, 33 and connection pads for electrical connection of the LED packages in series circuits as will be described below.

Eight of the LED packages 2 are arranged in an outer annular pattern or ring, and another eight of the LED packages 2 are arranged in an inner annular pattern or ring. The two annular patterns are substantially concentric with one another. The LED packages of the two annular patterns angularly offset from one another so that each LED package occupies a unique angular position in the concentric arrangement.

The electrically conductive circuits 32, 33 connect the LED packages in series, with the eight LED packages on the outer ring connected in one series circuit 32 and the eight LED packages on the inner ring connected in another series circuit 33. Each series circuit 32, 33 terminates at a respective pair of connection pads 34, 35, for electrical connection of the series circuits of LED packages to external circuitry.

Each LED package 2 is mounted on a respective tab 36 formed in the base layer 31 of the circuit board.

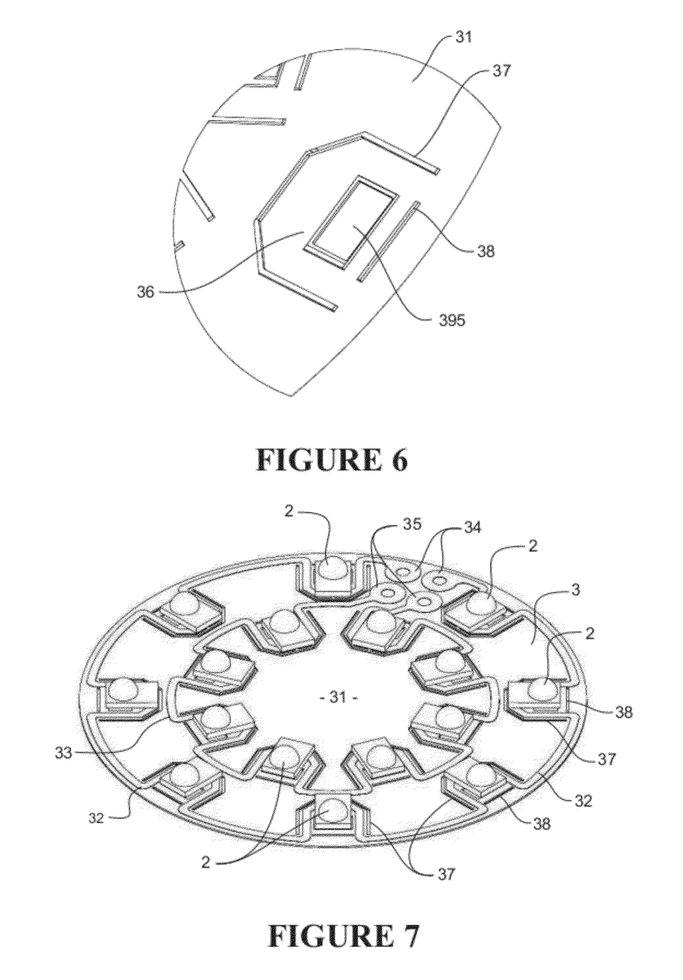

FIGS. 5 and 6 respectively show front and rear side views of one of the circuit board tabs 36. Each tab is formed by creating a U-shaped perimeter slot 37 in the base layer of the circuit board. The perimeter slot defines peripheral edge portions of the tab. A hinge slot 38 is formed respectively at the proximal end of each tab to provide each tab with a respective hinge line about which the tab preferentially hinges, as will be explained below. The perimeter slots 37 and hinge slots 38 are preferably cut in the circuit board 3 by a stamping process.

At each tab 36, the base layer 31 of the circuit board 3 is provided with a respective aperture 395. The aperture provides access to the thermal pad 24 on the rear side of the LED package 2 mounted on the tab 36. The apertures 395 are preferably formed by the same stamping process by which the perimeter slots 37 and hinge slots 38 are formed.

Each of the electrically conductive circuits 32, 33 is made up of a series of conductive tracks, two of which extend onto each respective tab 36, by passing between the ends of the respective peripheral-edge-defining U-shaped perimeter slot 37 and the ends of the respective hinge slot 38. The two tracks terminate on the tab 36 at respective connection pads 39 for connection to the anode and cathode terminals 22 on the rear side of the respective LED package on that tab. The anode and cathode terminals 22 are soldered to the respective connection pads 39 on the tabs 36 to attach the LED packages to the circuit board.

FIG. 7 shows a perspective view of the front side of the circuit board 3, after the LED packages 2 have been mounted on, and soldered to, the circuit board at an intermediate step in the manufacture of the LED array 1 of FIG. 1. At subsequent manufacturing steps, the circuit board 3, with the LED packages, is attached to the heat transfer plate 4, and the LED packages tilted to provide the LED array shown in FIG. 1.

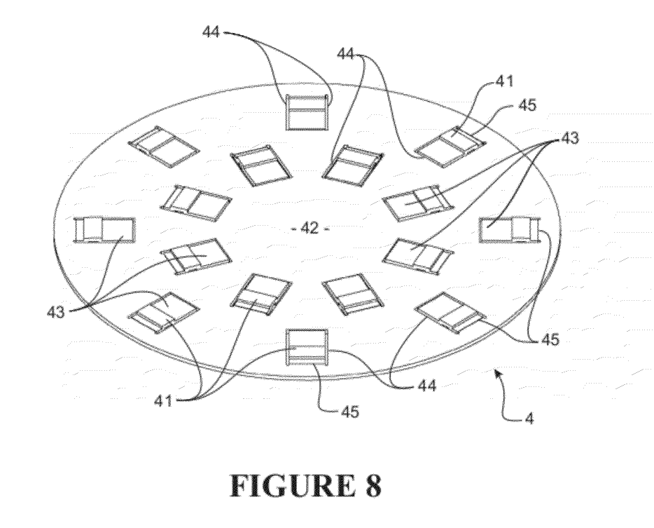

FIGS. 2 and 8 show the heat transfer plate 4 which is formed from a substantially planar sheet of thermally conductive material, for example copper. Localised protrusions 41, seen in FIGS. 2, 3 and 8, extend from a front side face 42 (the uppermost face seen in FIGS. 2, 3 and 8) of the heat transfer plate. Each of the protrusions 41 extends above the surrounding surface of the thermally conductive sheet by a distance that is greater than the thickness of the circuit board 3. This ensures that an air gap 50, shown in the cross-sectional view of FIG. 3, remains between the rear side of the circuit board 3 and the front side of the heat transfer plate 4 when these two parts are assembled together as explained below.

Each protrusion 41 is located on a respective heat transfer tab 43 formed in the heat transfer plate 4. Each heat transfer tab is formed by creating a U-shaped perimeter slot 44 in the heat transfer plate. This slot defines peripheral edge portions of the heat transfer tab. A hinge slot or a line of weakness 45 may be formed respectively at the proximal end of each heat transfer tab to provide each heat transfer tab with a respective hinge line about which the tab can preferentially hinge. In preference to cutting completely through the plate to form a slot, the heat transfer plate is made thinner at the line of weakness 45. Any reduction in the thermal conductance between the tab 43 and the remainder of the heat transfer plate 4 incurred by the thinning is less than would be incurred by the hinge slot. The thinning may be provided by compressing the heat transfer plate at the line of weakness.

The sheet of thermally conductive material is preferably stamped to simultaneously form the protrusion 41, the U-shaped perimeter slots 44, and the hinge slots or lines of weakness 45. This stamping is preferably done simultaneously with the cutting of the heat transfer plate from the sheet.

As seen in the LED array 1 shown in FIG. 1, the circuit board 3 and the heat transfer plate 4 are located face to face with one another. As shown in the cross-sectional view of FIG. 3, each protrusion 41 of the heat transfer plate 4 is aligned with, and extends at least partially through, a respective one of the apertures 395 in the circuit board 3.

The thermal pads 24 on the rear side of each LED package 2 are aligned over a respective one of the apertures 395 in the circuit board tabs 36 and soldered to a respective protrusion 41 of the heat transfer plate 4 to secure the LED packages 2, the circuit board 3 and heat transfer plate 4 together.

As seen in FIG. 1, the LED packages 2 are tilted upward and away from the general plane of the base layer of the circuit board so that when light is emitted from the array of LED packages the emitted light has a wider beam spread than if the LED packages were not tilted. The widening of the beam and the evenness of light emitted from the array are enhanced because each LED package is tilted about a respective axis corresponding to its unique angular position in the concentric arrangement of LED packages.

As seen in the LED array 1 shown in FIGS. 1, 9 and 10, each of the LED packages 2 is tilted, preferably by about 15 degrees, away from the general plane of the base layer of the circuit board. In other embodiments, the LED packages are tilted to other angles, for example to 60 or 75 degrees or more to the general plane of the base layer of the circuit board. At least one of the LED packages may be tilted at an angle of less than about 90 degrees relative to the adjacent portion of the face of the substructure. Each of the LED packages in an array can be tilted to a unique angle, or all or some LED packages in an LED array can be tilted by substantially the same amount.

FIG. 11 shows an elevation, or side edge view, of a LED array 101 having LED packages 102, 103 arranged in inner and outer concentric annular patterns, similar to the array shown in FIG. 1. In the array shown in FIG. 11, the LED packages 102 on the outer annular pattern have each been tilted downward through about 75 degrees in their respective radial planes, whereas the LED packages 103 on the inner annular pattern have each been tilted downward through about 15 degrees in their respective radial planes. By tilting at least some of the LED packages, a lamp using the LED array 101 emits a relatively even spread of light over a wide beam angle. It is envisaged that LED arrays using tilted LED packages, as described in this specification, will meet Energy Star requirement for integral LED lamps.

The LED arrays are preferably assembled in a two-stage soldering process. In a first stage, the LED packages 2 are mounted on the circuit board 3 by a standard commercial soldering process. Solder paste, which typically includes a flux, is applied to the circuit board connection pads 39 using standard screen printing, pin transfer or jet printing techniques. The LED packages are then positioned on the circuit board using a high throughput surface mount technology (SMT) machine. The anode and cathode terminals 22 of the LED packages are aligned over respective connection pads 39 of the circuit tracks on the circuit board tabs 36. The thermal pad 24 on the rear side of each LED package is aligned over the respective aperture 395 formed in the circuit board. Typically, the solder paste has sufficient tackiness to hold the LED packages in position while the circuit board is moved to the first soldering oven.

The circuit board 3, with positioned LED packages 2, is passed through a standard re-flow oven to heat the assembly by convection. Every component of the assembly is subjected to the highest re-flow temperature in the oven, typically above 230° C. The heated solder paste re-flows to make electrical connection between each of the anode and cathode terminals 22 of the LED packages, and respective connection pads 39 of the circuit tracks on the circuit board tabs 36. The circuit board assembly, with attached LED packages, is cooled to solidify the soldered connections. The LED packages are attached to the circuit board by these soldered connections. After completion of this first soldering stage, the thermal pads 24 of the LED packages may be seen through the respective apertures 395.

In a second stage, solder paste is applied to the top of the protrusions 41 using standard screen printing, pin transfer or jet printing techniques. The prepared and cooled circuit board assembly, with attached LED packages, is then positioned onto the heat transfer plate with the thermal pads 24 of the LED packages resting on respective protrusions 41.

After positioning the circuit board 3, with attached LED packages 2, on the heat transfer plate 4, the combination is moved in the second soldering stage across a series of heated plates to re-flow the solder paste on the protrusions. This re-flow makes a thermally conductive connection between the thermal pads 24 of the LED packages and respective heat transfer tabs 43 of the heat transfer plate. The circuit board, with attached LED packages, is attached to the heat transfer plate by these soldered connections of the thermal pads.

It is to be understood that in this second soldering stage, the soldering of the thermally conductive connections between the LED packages and the heat transfer plate is preferably performed by a heat conduction process, whereas, in the first solder stage, the soldering of the electrical connections between the LED packages and the circuit board is performed by a heat convection process. The circuit board floats above the heat transfer plate, being suspended from the LED packages which rest on the protrusions of the heat transfer plate. The circuit board is suspended from the LED packages by the already-soldered electrical connection between the anode and cathode terminals of the LED packages, and the circuit board tracks. The LED packages are supported with their respective thermal pads resting on the solder paste located on the tops of the respective protrusions, in readiness for soldering in the second soldering step.

In the second soldering stage, it is imperative to keep the already-soldered electrical connections below the solder melting temperature. In a preferred method of achieving this, the height of the stamped protrusions are controlled such that after assembly of the LED array the gap 50, shown labelled in the cross-sectional view of FIG. 3, is more than 0.15 mm. This air-gap provides a relatively non-conductive thermal barrier that prevents, or at least resists, direct conduction of heat from the heat transfer plate 4, through the base layer of the circuit board, to the already-soldered electrical connection between the terminals 22 of the LED packages and the circuit connection pads 39 on the tabs 36 of the circuit board. This thermal barrier maintains the soldered connections made in the first solder step in a solid, i.e. non-molten state, by maintaining these connections at a temperature below the solder melting temperature. As described above, the base layer 31 of the circuit board is made from a material, for example a polyimide, having a relatively low thermal conductivity which resists significant thermal conduction of heat to the already-soldered electrical connections made in the first soldering stage.

Preferably, each of the protrusions 41 extends above the surrounding surface of the thermally conductive sheet of the heat transfer plate 4 by a distance that is greater than the combined thickness of the electrically conductive circuit 32, 33 and the base layer 31 of the circuit board 3. This greater distance ensures the provision of the air gap 50 described in the previous paragraph.

The assembly comprising the circuit board 3, with attached LED packages 2, and the heat transfer plate 4 is placed successively on each heated hot plate, with the copper thermal transfer plate 4 of the assembly successively in thermally conductive contact with each of the heated plates. This thermally conductive contact enables rapid heating, for example to 235° C., and re-flow of the solder paste deposited on the tops of the protrusions 41, while the thermal barrier created by the air gap 50 and the low thermal conductivity of the circuit board base layer slows concomitant heating of the already-soldered electrical connections which are thus maintained below the solder melting temperature.

Each plate is pre-heated to a predetermined temperature so that the assembly can be heated to a predetermined profile of temperature versus time as the assembly passes across the series of heated plates. The temperature v time profile typically undergoes five phases:
Preheat. The assembly is brought from room temperature to preheat the assembly and evaporate solvents from the solder paste. A slow ramp up rate will reduce damage due to thermal shock. The duration and temperature required to evaporate the solvents will depend upon the solder paste used.
Flux activation. The solder paste is heated to a temperature in which the flux will react with oxide and contaminants on the surfaces to be joined. The duration and temperature of this phase are made sufficient to allow the flux to fully clean these surfaces without exhausting the flux before soldering takes place.
Thermal equalization. The assembly temperature is equalized to a temperature that is approximately 20° C. to 40° C. below the peak solder re-flow temperature. The temperature is insufficient to melt the already soldered electrical connection. The duration and temperature of this phase will depend upon the mass and the materials of the assembly components.
Re-flow. The assembly is briefly brought to a temperature sufficient to produce re-flow of the solder for soldering the thermal pad to the protrusion of the heat transfer plate, but without melting the solder of the already soldered electrical connection.
Cool down. This final phase in the conductive heating solder process allows the assembly to cool gradually back to room temperature.

The conductive heating solder re-flow process provides soldered connections in the shortest possible time without causing thermal shock to the components. The purpose is to produce a fine grain structure in the solder joint giving a joint with good fatigue resistance.

The durations of the five stages identified above are not necessarliy identical. The assembly may need to be held at each stage for a different duration to achieve the desired temperature-time profile. This can be achieved by controlling the speed at which the assembly is moved over the heated plates, or by controlling the timing of the transfer of the assembly from one heated plate to the next, or by moving the assembly at a constant speed over heated plates of different lengths or by using more than one heated plate in a stage. Several plates heated to different temperatures may be used to achieve a desired rate of change of temperature versus time within a stage.

The conductive heating of the second soldering step achieves selective heating of different parts of the assembly because the circuit board 3 floats on top of the copper heat transfer plate 4 with only the heat transfer plate in contact with the heated plates. The heat transfer plate, being made of copper or another suitable material, has a high thermal conductivity. This enables the solder between the tops of the protrusions 41 and the thermal pads 24 on the rear (i.e. under) side of the LED packages 2 to be selectively heated to the solder melting temperature, for example 235° C., before the already-soldered electrical connections between the connection pads 39 on the tabs 36 of the circuit board 3 and the anode and cathode terminals 22 of the LED packages 2. The air gap 50 between the circuit board 3 and the heat transfer plate 4, and the relatively high thermal resistivity of the base layer of the circuit board, reduces and slows heat transfer to the soldered connections made in the first soldering step, preventing the solder of those connections from reaching the solder melting temperature.

The thickness of the solder interface between the thermal pads of the LED packages and the tabs of the heat transfer plate is critical to the thermal performance of the LED array. Research indicates that increasing the thickness of a solder interface from 10 to 30 microns decreases the thermal conductivity of the interface from 50° C./W to 14° C./W. While solder thickness should be as thin as possible, manufacturing practicalities limit practical solder thicknesses to about 10 to 15 microns.

In theory, the two soldering steps could be performed simultaneously, especially when, in each LED package, the surface of the anode and cathode terminals 22 and the thermal pad typically lie in the same plane. But, because the circuit board and the heat transfer plate are prepared by distinctly separate processes, it is difficult in a manufacturing environment to align the electrical connection pads 39 of the circuit board 3 precisely in the same plane as the tops of the protrusions 41 on the heat transfer plate 4. The inevitable misalignment means that thicknesses of solder interfaces are unpredictable. It is unlikely that solder thicknesses down to the 10 to 15 micron range could be reliably achieved for the connections between the thermal pads of the LED packages and the heat transfer plate.

The splitting of the soldering into the two steps describe above provides a simple means for ensuring control of the thickness of solder in the thermal connections. For example, if the solder paste is screen printed onto the protrusions, the thickness of the printed solder can be controlled by controlling the height of the protrusions or by selecting the appropriate stencil thickness. By using a 0.075 mm thick stencil and setting the protrusion height to be 0.060 mm during stamping of the heat transfer plate, thicknesses of the printed solder in the range of 0.010 to 0.020 mm are achievable and within typical manufacturing tolerances. The protrusions sit in pockets of the stencil while printing and this location of the protrusions allows the solder thickness to be controlled.

Another advantage of splitting the soldering process into the two steps is the increased reliability of solder printing. The distances between the thermal pad and the anode and cathode terminals of the LED package are very small, requiring cutouts in the screen printing stencils to be very close. This diminishes the reliability of the solder printing. The splitting of the solder process into the two steps, the first step for the electrical connections and the second step for the thermal connections, ensures more stability and reliability in the manufacturing process.

After completion of the second soldering stage, the LED packages 2 are tilted to increase the dispersion of light emitted from the LED array 1. The tilting is possible because each LED package is mounted on a tab 36 of the circuit board and a tab 43 of the heat transfer plate, and the heat transfer plate and the base layer and conductive tracks of the circuit board are flexible. The combination of this flexibility with the hinging lines provided by the hinge slot 38 at the proximal end of each circuit board tab 36 and by the hinge slot or line of weakness 45 formed at the proximal end of each tab 43 of the heat transfer plate allows the LED packages 2 to be tilted out of the general plane of the circuit board and heat transfer plate. The tilting LED packages rotate about the respective tab hinge lines which are substantially circumferentially aligned in the concentric annular patterns described above. Each LED package rotates through a unique radially-aligned plane defined by the unique position of the LED package in the concentric arrangement of LED packages described above. The circuit board and the heat transfer plate, other than their respective tabs, are each substantially planar.

The prepared assembly of LED packages 2 mounted on the circuit board 3 and heat transfer plate 4 is placed, with the LED packages facing downward, on a die. A multi-headed punch tool, with a respective tool head aligned over each pair of circuit board and heat transfer plate tabs is pressed down against the tabs in the heat transfer plate to tilt the tabs, and the respective LED packages, toward and into corresponding recesses formed in the die.

The tilting of the LED packages 2 is facilitated by the formation of the tabs 36, 43 by the U-shaped perimeter slots 37, 44, and the hinge slots or lines of weakness 38, 45, in the circuit board 3 and heat transfer plate 4, respectively. Although the formation of these tabs by these means is preferred, the LED packages may still be tilted without forming the tabs in this way. For example, the LED packages 2 could be tilted without having formed the U-shaped perimeter slots 44 in the heat transfer plate 4; the heat transfer plate being deformed and stretched to provided a respective tilted tab zone under each LED package.

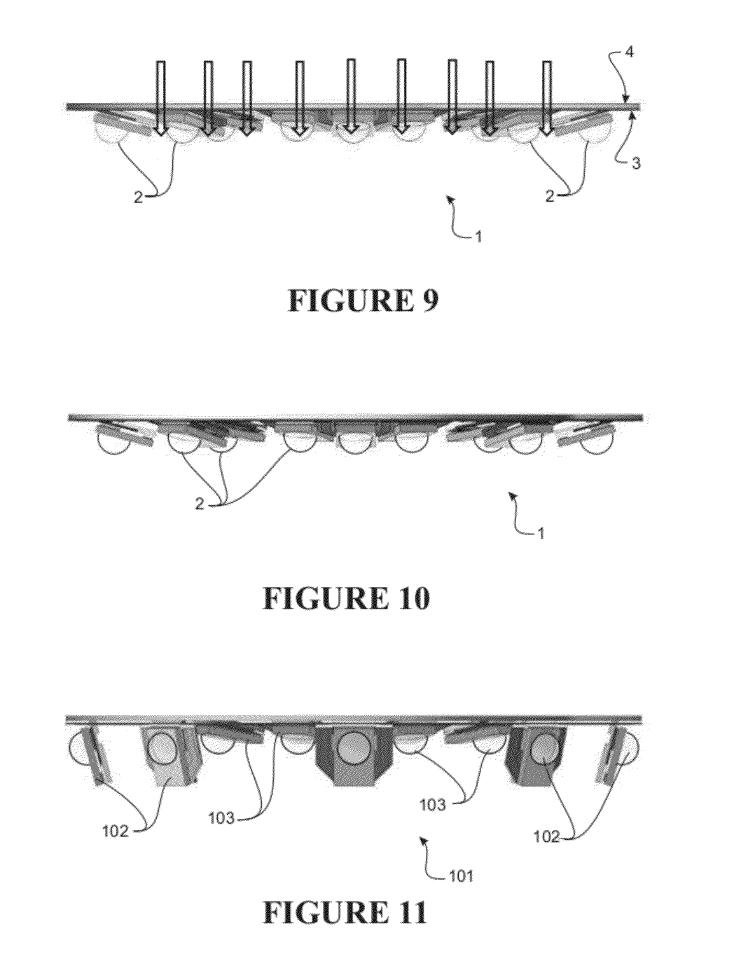

FIG. 9 shows a side view of the finished LED array 1 seen in FIG. 1, with parallel arrows representing the direction of movement of respective individual tool heads of the punch used to tilt some of the LED packages.

FIG. 10 shows a side view of the finished LED array 1 seen in FIG. 1, with individual LED packages tilted at about 15 degrees to the general plane of the circuit board and heat transfer plate.

FIG. 11 shows a side view of the an alternative LED array, with some of the LED packages tilted at about 15 degrees, and others at about 75 degrees, to the general plane of the circuit board and heat transfer plate.

The multi-headed punch tool is provided with an individual tool head portion for each of the LED packages that are to be tilted. The tilt angle of each LED package may be individually configured, with all, or only one, or some, of the LED packages being tilted. LED packages can be individually tilted to predetermined tilt angles to meet Energy Star, or other, criteria for uniform light distribution over wide spread angles.

The current in the series circuits of LED packages can be individually controlled to adjust or vary the light intensity directed to specific locations to achieve a more even distribution of light or to achieve a particular desired uneven distribution of light.

The finished LED array 1, as shown in FIG. 1, 10 or 11, is suitable for incorporation into an LED lamp.

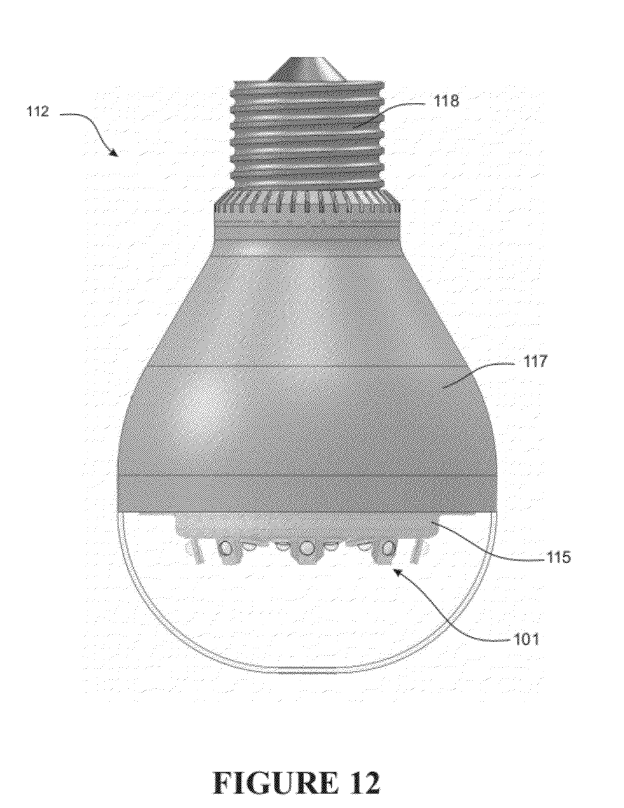

FIG. 12 shows an LED lamp 112 incorporating the LED array 101 shown in FIG. 11. The LED array 101 is connected by a thermally-conductive heat sink base 115, to a heat sink located inside a vented enclosure 117 for dissipation of heat from the LED packages to ambient surroundings during operation of the LED lamp. The heat transfer plate of the LED array is attached to the heat sink base 115 by a soldering, resistive welding, swaging, crimping or ultrasonic welding process. The heat sink inside the enclosure 117 is preferably finned.

The circular heat transfer plate of the LED array 101 is made from copper and is welded ultrasonically or swaged or crimped to the circular heat sink base 115. The diameters of the copper heat transfer plate and heat sink base are substantially identical. The heat sink base is of copper or aluminium and is about 1-2 mm thick. Heat sink fins are crimped or welded onto the heat sink base. The fins are substantially perpendicular to the heat sink base, are spaced apart from one another, preferably evenly, and are arrayed radially. The heat sink base may have tabs that are similar to the tabs 43 of the heat transfer plate, in which case the tabs of the heat sink base are welded ultrasonically or swaged or crimped to the tabs of the heat transfer plate to provide for good dissipation of heat away from the LED packages. The heat sink fins are surrounded by the vented enclosure 117 to encourage vertical air movement over the surfaces of the fins when the lamp is operated in the typical orientation shown in FIG. 12, i.e. with the major axis of the lamp vertical and the electrical connection and mounting base 118 uppermost.

Specific embodiments of the invention have been described above by way of example only, and modifications and improvements as would be obvious to those skilled in the art may be made to the invention without departing from the scope of the invention as defined by the following claims.

In one such modification, the slots defining the edge portions or hinge lines of the tabs of the circuit board or heat transfer plate are not continuous but are instead formed by a series of perforations or holes. By using this modification, the tabs in the circuit board and heat transfer plate can be retained more precisely in coplanar alignment with the remainder of the respective circuit board or heat transfer plate until the un-perforated zones between the perforations are ruptured when the tabs and LED packages are tilted after completion of the two soldering steps. The more precise coplanar alignments allow better control of the thickness of the solder which, as described above, is desirable in manufacture of LED arrays having a low thermal resistance between LED packages and heat sink.

Multiple LED packages may be mounted and arranged on circuit boards and heat transfer plates similarly to the LED array described above, but with circuit boards and heat transfer plates of non-circular shape and/or with the LED packages arranged in patterns other than the concentric annular patterns described. For example, the circuit boards and heat transfer plates may be rectangular or polygonal, and the LED packages may be arranged in rows and/or columns.

Although a LED array is described above as having eight LED packages arranged in each of two concentric annular patterns, LED arrays according to the invention may have other patterns of LED packages, the number of patterns of LED packages may be one or more, the number of LED packages in each pattern may be one or more, and the number of LED packages in each pattern may be the same or different.

Although a LED lamp may use only a single array as described above to achieve widely dispersed and even distribution of emitted light, LED lamps may use two or more such LED arrays to provide even better dispersion and/or evenness of emitted light.

What is claimed is:

1. A light emitting diode (LED) array comprising an assembly of LED packages, wherein:
the LED packages are mounted to a face of a substructure;
the substructure comprises a circuit board and a heat transfer plate;
each LED package comprises electrical connection terminals and a thermal connection pad;
the electrical connection terminals are electrically connected to respective circuit conductors of the circuit board;
the thermal pads are connected to the heat transfer plate by respective thermally conductive connections; and
at least one of the LED packages is tilted at an angle relative to an adjacent portion of the face of the substructure.

2. A LED array as claimed in claim 1, wherein:
the circuit board comprises a respective tab for each LED package;
portions of the circuit conductors extend onto each tab; and
the electrical connections of the electrical connection terminals to the respective circuit conductors are made at the portions of the circuit conductors on the respective tabs.

3. A LED array as claimed in claim 2, wherein:
the circuit board comprises an electrically insulative base layer;
the circuit conductors are formed on a face of the base layer; and
peripheral edge portions of each tab are defined respectively by at least one perimeter slot formed through the base layer of the circuit board.

4. A LED array as claimed in claim 3, wherein:
each tab comprises a hinge line provided by a respective hinge slot formed through the base layer of the circuit board.

5. A LED array as claimed in claim 4, wherein:
each tab comprises an aperture formed through the base layer; and
the thermally conductive connection of the thermal pad of a respective LED package to the heat transfer plate is made through the aperture.

6. A LED array as claimed in claim 5, wherein:
localised protrusions extend from a face of the heat transfer plate; and
the thermally conductive connections of the thermal pads of the LED packages are made respectively to the protrusions of the heat transfer plate.

7. A LED array as claimed in claim 1, wherein:
the circuit board comprises a respective tab for each LED package;
each tab comprises an aperture formed through the circuit board;
localised protrusions extend from a face of the heat transfer plate;
each protrusion extends at least partially through a respective one of the apertures; and
the thermally conductive connections of the thermal pads of the LED packages are made respectively to the protrusions.

8. A LED array as claimed in claim 7, wherein:
each of the localised protrusions extends above adjacent portions of the face of the heat transfer plate by a distance that is greater than the thickness of the circuit board;the heat transfer plate comprises a heat transfer tab for each respective LED package;
the localised protrusions are located respectively on the heat transfer tabs; and
peripheral edge portions of each heat transfer tab are defined respectively by at least one perimeter slot formed through the heat transfer plate.

9. A LED array as claimed in claim 8, wherein at least one of the LED packages is tilted at an angle of 15-90 degrees relative to the adjacent portion of the face of the substructure.

10. A method of manufacturing a light emitting diode (LED) array comprising an assembly of LED packages, each LED package comprising electrical connection terminals and a thermal connection pad; the method comprising:
mounting the LED packages to a face of a substructure comprising a circuit board and a heat transfer plate;
the mounting being performed by:
connecting the electrical connection terminals of each LED package to circuit conductors of the circuit board by respective electrical connections; and
connecting the thermal pads to the heat transfer plate by respective thermally conductive connections;
and, subsequently to mounting the LED packages to the substructure;
tilting at least one of the LED packages at an angle relative to an adjacent portion of the face of the substructure.

11. A method of manufacturing a LED array as claimed in claim 10, wherein:
a respective localised protrusion is formed on a face of the heat transfer plate for each LED package; and
the thermally conductive connections are made by:
placing solder paste on each protrusion;
placing the LED packages on the heat transfer plate with the thermal pads aligned respectively with, and resting on, the solder paste on the protrusions; and
temporarily melting the solder paste on the protrusions to form the thermally conductive connections.

12. A method of manufacturing a LED array as claimed in claim 11, wherein the step of temporarily melting the solder paste on the protrusions is performed by placing the heat transfer plate on at least one heated plate, with the heat transfer plate in thermally conductive contact with the heated plate, to heat and temporarily melt the solder paste on the protrusions by conduction of heat from the heated plate.

13. A method of manufacturing a LED array as claimed in claims 11, wherein the step of temporarily melting the solder paste on the protrusions is performed by placing the heat transfer plate successively on each plate of a series of heated plates, with the heat transfer plate successively in thermally conductive contact with each of the heated plates, to heat and temporarily melt the solder paste on the protrusions by conduction of heat from the heated plates, and wherein each plate of the series of heated plates is heated to a different temperature.

14. A method of manufacturing a LED array as claimed in claim 11, wherein each of the localised protrusions extends above adjacent portions of the face of the heat transfer plate by a distance that is greater than the thickness of the circuit board.

15. A method of manufacturing a LED array as claimed in claim 11, wherein:
the electrical connections are made by soldered connections by:
placing solder paste on each of the circuit conductors;
placing the LED packages on the circuit board with the electrical connection terminals aligned respectively over the solder paste on the circuit conductors; and
temporarily melting the solder paste on the circuit conductors to form the electrical connections.

16. A method of manufacturing a LED array as claimed in claim 15, wherein:
a respective aperture is formed in the circuit board for each LED package;
in the step of placing the LED packages on the circuit board, the LED packages are placed on the circuit board with the thermal pads aligned respectively over the apertures; and
in the step of placing the LED packages on the heat transfer plate, the circuit board, with the LED packages attached to the circuit board by the soldered electrical connections, is placed over the heat transfer plate with the protrusions respectively extending at least partially through the apertures.

17. A method of manufacturing a LED array as claimed in claim 16, wherein:
each aperture is located on a respective tab;
each tab is formed by creating at least one perimeter slot through the circuit board to define peripheral edge portions of the respective tab;
portions of the electrical conductors are located on each tab;
the electrical connections are made respectively to the portions of the electrical conductors located on the tabs; and
each tab comprises a hinge line provided by a respective hinge slot formed through the circuit board.

18. A method of manufacturing a LED array as claimed in claim 17, wherein the heat transfer plate is a sheet of thermally conductive material and the localised protrusions are formed by stamping the sheet of thermally conductive material.

19. A method of manufacturing a LED array as claimed in claim 18, wherein each localised protrusion is located on a respective heat transfer tab formed in the heat transfer plate by creating perimeter slots through the heat transfer plate to define peripheral edge portions of the heat transfer tab.

20. A method of manufacturing a LED array as claimed in claim 19, wherein the tilting of the at least one LED package is performed by applying a punch against the heat transfer plate to move the at least one LED package away from the respective adjacent portion of the substructure.
